(19) United States
(12) Patent Application Publication
(10) Pub. No.: US 2010/0079558 A1
(43) Pub. Date: Apr. 1, 2010

(54) PIEZOELECTRIC ELEMENT, LIQUID EJECTING HEAD, AND LIQUID EJECTING APPARATUS

(75) Inventor: Masato Shimada, Chino-shi (JP)

Correspondence Address: Workman Nydegger;1000 Eagle Gate Tower, 60 East South Temple, Salt Lake City, UT, 84111, US

(73) Assignee: SEIKO EPSON CORPORATION, Tokyo (JP)

(21) Appl. No.: 12/568,246

(22) Filed: Sep. 28, 2009

(30) Foreign Application Priority Data
Sep. 29, 2008 (JP) 2008-250953
Jun. 11, 2009 (JP) 2009-139763

(51) Int. Cl. B41J 2/045; H01L 41/04

(52) U.S. Cl. 347/71; 310/367; 310/340

(57) ABSTRACT

A piezoelectric element includes in a laminated state a piezoelectric layer, a first electrode formed on a first surface of the piezoelectric layer, and a second electrode formed on a second surface of the piezoelectric layer which is opposite to the first surface. The piezoelectric layer has a film thickness of 5 μm or less, and has a flat portion formed as a second surface in parallel with the first surface, and a lateral portion inclined downwardly from the flat portion towards the first surface. The second electrode has a central portion formed in parallel with the flat portion, and a slope portion inclined downwardly from the central portion towards the flat portion. The inclination angle of the slope portion to the flat portion is gentle as compared with the inclination angle of the lateral portion to the first surface.

### BACKGROUND

1. Technical Field

The present invention relates to a piezoelectric element which is employed as a drive source for a liquid ejecting head, such as an ink jet-type recording head, the liquid ejecting head, and a liquid ejecting apparatus, and more particularly, to a piezoelectric element capable of improved durability by suppressing stress concentration when the piezoelectric element is displaced, a liquid ejecting head, and a liquid ejecting apparatus.

2. Related Art

For example, a liquid ejecting apparatus is equipped with a liquid ejecting head capable of ejecting a liquid, the liquid ejecting apparatus ejecting various liquids from the liquid ejecting head. A typical example of the liquid ejecting apparatus is an image recording apparatus, such as an ink jet-type printer, equipped with an ink jet-type recording head (hereinafter referred to as a recording head) as the liquid ejecting head, in which liquid ink is ejected and impacted onto a recording medium (ejection target), such as a recording paper, from nozzle orifices of the recording head to form dots and thus perform recording of, for example, an image. Recently, the liquid ejecting apparatus has been applied to various manufacturing apparatuses, such as an apparatus for manufacturing a color filter for a liquid crystal display, as well as the image recording apparatus.

In the liquid ejecting head, a piezoelectric element used as a driving source to eject a liquid, that is, a pressure generating unit that induces pressure fluctuation in the liquid positioned in a fluid passage of the liquid ejecting head, is an element with a piezoelectric layer made of piezoelectric material which is sandwiched between electrodes. One example of the piezoelectric element is disclosed in JP A-2008-119968. More specifically, the piezoelectric element includes a lower electrode film, a piezoelectric layer (laminated structure of piezoelectric films) made of lead zirconate titanate (PZT) and the like, and an upper electrode film, in which the layer and the films are laminated to have a desired film thickness by using a film-forming technique. The piezoelectric layer and the electrode films are patterned and cut into pieces in each pressure-generating chamber by a lithography and etching method.

The piezoelectric element manufactured by each of the film-forming, lithography and etching processes can be driven at high speed, since it is formed to have an accurate, thin shape. The piezoelectric element has the total thickness of, for example, several micrometers. In particular, a piezoelectric element having a film thickness of 5 μm or less is hereinafter referred to as a thin film piezoelectric element. Since the upper electrode film among the films constituting the thin film piezoelectric element is displaced to a greater degree by the deformation of the piezoelectric element, the thickness changes to a range of 0.0x μm to 0.x μm (i.e., several micrometers from 2 decimal places to 1 decimal place).

In the above-described thin film piezoelectric element, since stress is likely concentrated on both end portions of the upper electrode film in width direction thereof (short-length direction of an element) during displacement driving, the upper electrode film may be damaged due to the repetitive displacement. For this reason, there is a need to prolong the lifespan of the piezoelectric element.

Although the thin film piezoelectric element includes a protective film for covering the entire surface of the piezoelectric element in order to protect the piezoelectric element from the moisture contained in the air, there is a case where the protective film has insufficient thickness at the edge (corner) of the upper surface thereof. For this reason, regard is paid to incline the lateral surface of the piezoelectric element at an angle of, for example, 10° to 90° to a substrate (e.g., a passage forming substrate), thereby further increasing the angle of the corner of the upper electrode film and thus ensuring the coating thickness of the protective film.

However, the end portion of the active part serving as a substantial displacement driving part is defined in the piezoelectric element by the end portion of the lower electrode film and the end portion of the upper electrode film. Therefore, if a portion of the piezoelectric layer extending outwardly beyond the end portion of the upper electrode film, i.e., a non-active part, is enlarged by inclining the side as described above, the stress is concentrated on the boundary portion between the non-active part and the active part whenever the piezoelectric layer is displaced, thereby causing crack in the piezoelectric layer, the vibration plate or the like and thus peeling each electrode from the piezoelectric layer.

### SUMMARY

An advantage of some aspects of the invention is that it provides a piezoelectric element capable of improved durability by suppressing stress concentration during displacement, a method of fabricating the piezoelectric element, a liquid ejecting head, and a method of manufacturing the liquid ejecting head.

An aspect of the invention is to provide a piezoelectric element including in a laminated state a piezoelectric layer, a first electrode formed on a first surface of the piezoelectric layer, and a second electrode formed on a second surface of the piezoelectric layer which is opposite to the first surface, wherein the piezoelectric layer has a film thickness of 5 μm or less, and has a flat portion formed as a second surface in parallel with the first surface, and a lateral portion inclined downwardly from the flat portion towards the first surface, the second electrode has a central portion formed in parallel with the flat portion, and a slope portion inclined downwardly from the central portion towards the flat portion, and the inclination angle of the slope portion to the flat portion is gentle as compared with the inclination angle of the lateral portion to the first surface.

With the above configuration, the lateral (end) shapes of both sides of the piezoelectric element in a short-length direction from the first electrode film to the central portion (upper surface) of the second electrode film through the lateral portion of the piezoelectric layer and the slope portion of the second electrode film are gentle overall. Therefore, it is possible to lessen stress concentration, in particular, stress concentration at both end portions of the second electrode film of the piezoelectric element in the short-length direction, when the piezoelectric element is driven. Also, since it is possible to prevent the lateral portion of the piezoelectric layer from being inclined above a desired inclination angle level, the stress concentration at the boundary between the non-active and active parts of the piezoelectric element can be lessened. As such, breakage of the piezoelectric element due to repeated displacement of the piezoelectric element can be suppressed. As a result, the durability of the piezoelectric element can be improved. In addition, since the thickness of the active part of the piezoelectric element is uniform, it can attempt to equalize the displacement amount or resistance of the piezoelectric element during driving. As such, the reduction of the loss causes the driving efficiency to improve, and rigidity against breakages such as cracks can be obtained.

In the above configuration, it is preferable that the second electrode covers the entire surface of the flat portion of the piezoelectric layer.

With this configuration, the lower inclined end of the slope portion in the second electrode is connected to the upper inclined end of the lateral portion in the piezoelectric layer. Since an electric field is effectively applied to the end portion in the short-length direction of the element, it is possible to enlarge the area of the active part of the piezoelectric element to the maximum extent, and thus, driving efficiency can be improved.

In the above configuration, it is preferable that the piezoelectric element further includes a protective layer that covers the first electrode, the piezoelectric layer and the second electrode.

With the above configuration, since the lateral shape of the piezoelectric element is wholly gentle, sufficient covering thickness of the protective film for protecting the piezoelectric element from moisture can be obtained, and the non-uniform thickness of the protective film can be reduced. In addition, the thickness of the protective film in the active part of the piezoelectric element may be made uniform, and the resistance against the deformation of the piezoelectric element during driving can be made even.

In the above configuration, it is preferable that the inclination angle of the slope portion of the second electrode to the flat portion is 2° or more and 20° or less.

### BRIEF DESCRIPTION OF THE DRAWINGS

The invention will be described with reference to the accompanying drawings, wherein like numbers reference like elements.

FIG. 1 is an exploded perspective view of a recording head.

FIGS. 2A to 2C are a plan view and cross-sectional views respectively illustrating a recording head.

FIGS. 3A to 3C are cross-sectional views illustrating a process of fabricating a recording head.

FIGS. 4A to 4C are cross-sectional views illustrating a process of fabricating a recording head.

FIG. 5 is a cross-sectional view of major components of a piezoelectric element to explain the distinctive configuration of the piezoelectric element.

FIGS. 6A to 6C are diagrams explaining a process of patterning a piezoelectric element.

### DESCRIPTION OF EXEMPLARY EMBODIMENTS

Hereinafter, a preferred embodiment of the invention will be described in detail with reference to the accompanying drawings. Although the invention is defined by various limitations as a preferable embodiment described below, the scope of the invention is not limited thereto unless there is explicit description limiting the scope of the invention. Also, an ink jet-type recording head (hereinafter merely referred to as a recording head) mounted on an ink jet-type printer (a kind of a liquid ejecting apparatus according to the invention) will be described by way of example of the liquid ejecting head according to the invention.

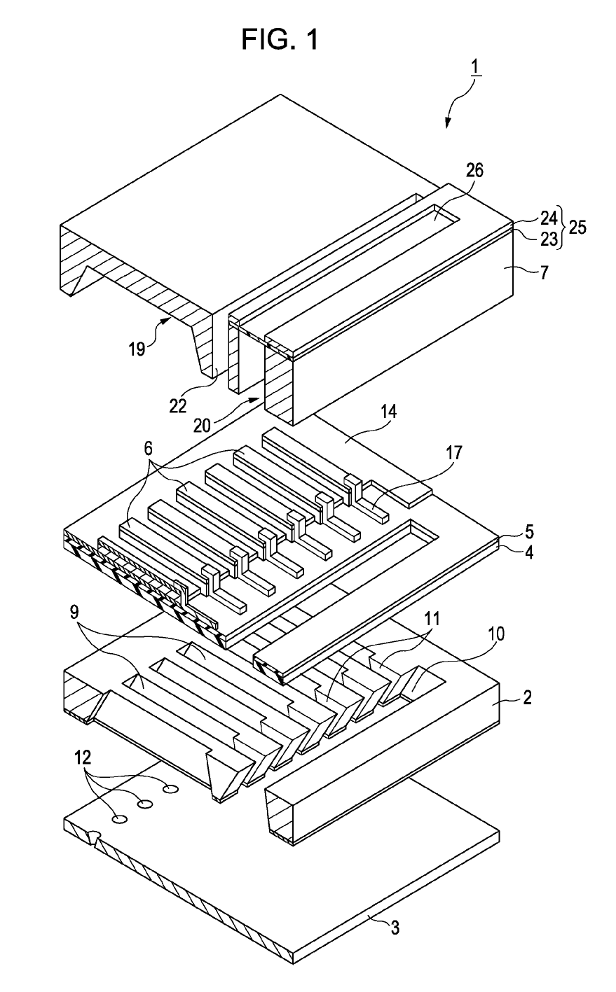

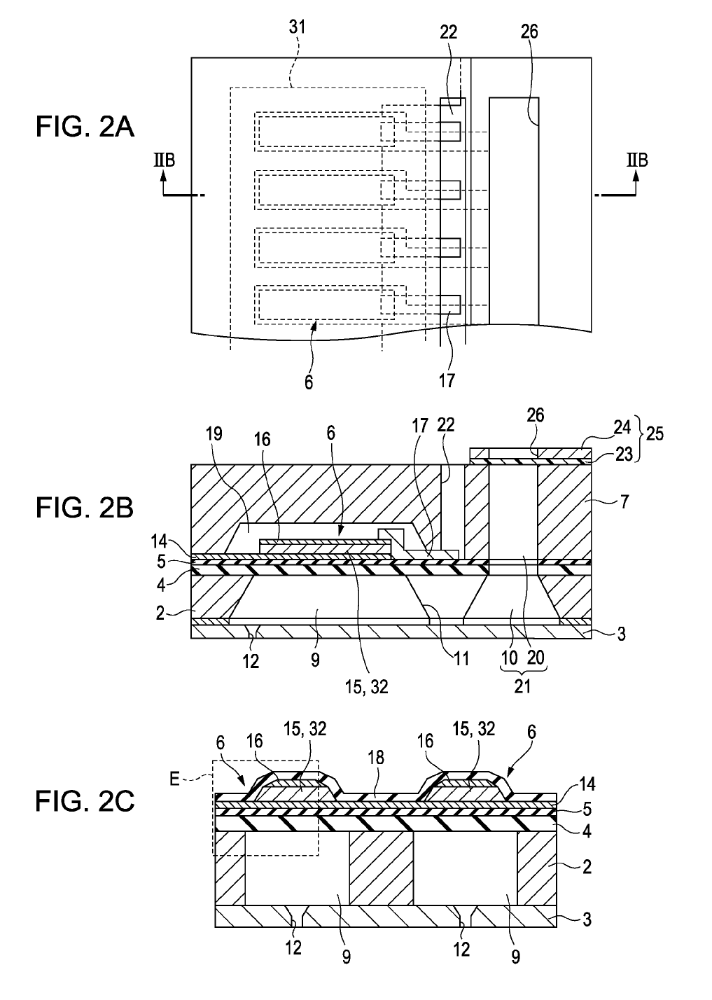

FIG. 1 is an exploded perspective view illustrating the configuration of a recording head 1 according to the embodiment. FIG. 2A is a plan view of the recording head 1, FIG. 2B is a cross-sectional view taken along the line IIB-IIB in FIG. 2A, and FIG. 2C is a cross-sectional view illustrating a major portion of a pressure-generating chamber 9 in a width direction (i.e., a short-length direction of a piezoelectric element). In this embodiment, the recording head 1 is composed of a passage-forming substrate 2, a nozzle plate 3, an elastic film 4, an insulation layer 5, a piezoelectric element 6, a protective substrate 7, and so forth which are stacked on each other.

The passage-forming substrate 2 is made of a single-crystal silicon substrate with a (110) crystal plane orientation in this embodiment. A plurality of pressure-generating chambers 9 are formed on the passage-forming substrate 2 in the width direction thereof. In addition, a communicating portion 10 is formed in a region of the passage-forming substrate 2 at the outer side of the pressure-generating chambers 9 in a longitudinal direction thereof. The communicating portion 10 communicates with each pressure-generating chamber 9 through a corresponding ink supply path 11 which is provided in the respective pressure-generating chambers 9. The communicating portion 10 also communicates with a reservoir portion 20 of a protective plate 7 which is to be described later, to constitute a part of a reservoir 21 which serves as a common ink chamber for the pressure-generating chambers 9. Each ink supply path 11 is formed to have a width smaller than that of each pressure-generating chamber 9, and thus the passage resistance of ink flowing from the communicating portion 10 into each pressure-generating chamber 9 is maintained at a constant level.

The nozzle plate 3 provided with nozzle orifices 12 is fixed to the open surface side of the passage-forming substrate 2 with an adhesive agent, a thermal adhesive film or the like, the nozzle orifices being in communication with an end portion of each pressure-generating chamber 9 which is opposite to the ink supply paths 11. The nozzle plate 3 is made of a glass ceramic material, a single-crystal silicon substrate, stainless steel or the like, which has a thickness of, for example, 0.01 mm to 1 mm, and a linear expansion coefficient of, for example, 2.5 to 4.5 (×10⁻⁶/° C.) at a temperature of 300° C. or less.

On the other hand, the elastic film 4 made of silicon dioxide (SiO₂) and having a thickness of, for example, approximately 1.0 μm is formed on the side of the passage-forming substrate 2 which is opposite to the open surface thereof. The insulation film 5 made of zirconium oxide (ZrO₂) and having a thickness of, for example, approximately 0.4 μm is formed on the elastic film 4. Moreover, a lower electrode film 14 (corresponding to the first electrode in the invention) having a thickness of, for example, approximately 0.2 μm, a piezoelectric layer 15 (piezoelectric film 32) having a thickness of, for example, approximately 1.0 μm, and an upper electrode film 16 (corresponding to the second electrode in the invention) having a thickness of, for example, approximately 0.05 μm are formed on the insulation layer 5 thereby constituting the piezoelectric elements 6 (thin film piezoelectric element) having a thickness of approximately 1.25 μm on the whole. Here, each piezoelectric element 6 is a part including the lower electrode film 14, the piezoelectric layer 15, and the upper electrode film 16. In general, the piezoelectric element 6 is formed by using any one of two electrodes as a common electrode, and then by patterning the other one of these electrodes and the piezoelectric layer 15 for each pressure-generating chamber 9. Parts which are formed of any one of the patterned electrodes and the patterned piezoelectric layer 15, in which piezoelectric strain occurs when a voltage is applied to two electrodes, are referred to as piezoelectric active parts. In this embodiment, the lower electrode film 14 is used as the common electrode of the piezoelectric elements 6, while the upper electrode film 16 is used as an individual electrode of the piezoelectric element 6. However, the functions of the lower electrode film 14 and the upper electrode film 16 may be reversed according to conditions of a drive circuit or wirings. In any case, the piezoelectric active part is formed for each pressure-generating chamber 9. In addition, a lead electrode 17 made of, for example, gold (Au), is connected to the upper electrode film 16 of the respective piezoelectric elements 6, and voltage is selectively applied to each piezoelectric element 6 via the lead electrode 17.

In this embodiment, the piezoelectric element 6 is wholly covered by a protective layer 18 made of any moisture-proof insulating material. Covering (coating) the piezoelectric element 6 with the protective layer 18 can prevent the piezoelectric element 6 from breaking due to moisture or the like contained in the air. The protective layer 18 may be made of a moisture-proof material, for example, an inorganic insulating material, such as silicon oxide (SiOₓ), tantalum oxide (TaOₓ), aluminum oxide (AlOₓ) and so forth, and an organic insulating material, such as polyimide (PI).

The protective plate 7 is bonded to the side of the piezoelectric element 6 formed on the passage-forming substrate 2, and has a piezoelectric element holding portion 19 which provides a region opposite to the piezoelectric element 6 with a space of a size which does not interfere with the displacement of the piezoelectric element. The protective plate 7 is provided with the reservoir portion 20 at a region corresponding to the communicating portion 10 of the passage-forming substrate 2. The reservoir portion 20 is formed in such a way to penetrate the protective plate 7 in the thickness direction thereof and extend in the width direction of the pressure-generating chambers 9. As described above, the reservoir portion 20 communicates with the communicating portion 10 of the passage-forming substrate 2 to constitute the reservoir 21 which serves as a common ink chamber for the respective pressure-generating chambers 9.

The protective substrate 7 is provided with a through-hole 22 penetrating the protective substrate 7 in the thickness direction thereof at a region between the piezoelectric element holding portion 19 and the reservoir portion 20. A portion of the lower electrode film 14 and the front end of the lead electrode 17 are exposed to the inside of the through-hole 22, and one end of the wiring of a driving IC which is not shown in the drawings is electrically connected to the lower electrode film 14 and the lead electrode 17. A compliance plate 25 constituted of a sealing film 23 and a fixing plate 24 is joined onto the protective plate 7. The sealing film 23 is made of a flexible material with low rigidity (e.g., a polyphenylene sulfide (PPS) film with a thickness of 6 μm). One side of the reservoir portion 20 is sealed with the sealing film 23. Meanwhile, the fixing plate 24 is made of a hard material such as a metal (e.g., stainless steel or the like with a thickness of 30 μm). Since the region of the fixing plate 24 which is opposite to the reservoir 21 is provided with an open portion 26 by completely removing the corresponding portion of the fixing plate 24 in the thickness direction thereof, one side of the reservoir 21 is sealed only by the flexible sealing film 23.

The recording head 1 of the above configuration is supplied with ink from an ink supply unit, and the inside of the recording head extending from the reservoir 21 to the nozzle orifices 12 is filled with the ink. After that, in accordance with a driving signal outputted from a printer controller (not shown) of a printer body, a voltage is applied between the lower electrode film 14 and the upper electrode film 16, which correspond to each pressure-generating chamber 9. This causes the elastic film 4, the insulation film 5, the lower electrode film 14, and the piezoelectric layer 15 to be flexibly deformed, so that the pressure in the pressure-generating chamber 9 is increased. By controlling the pressure fluctuation, ink droplets are ejected (discharged) from the nozzle orifices 12.

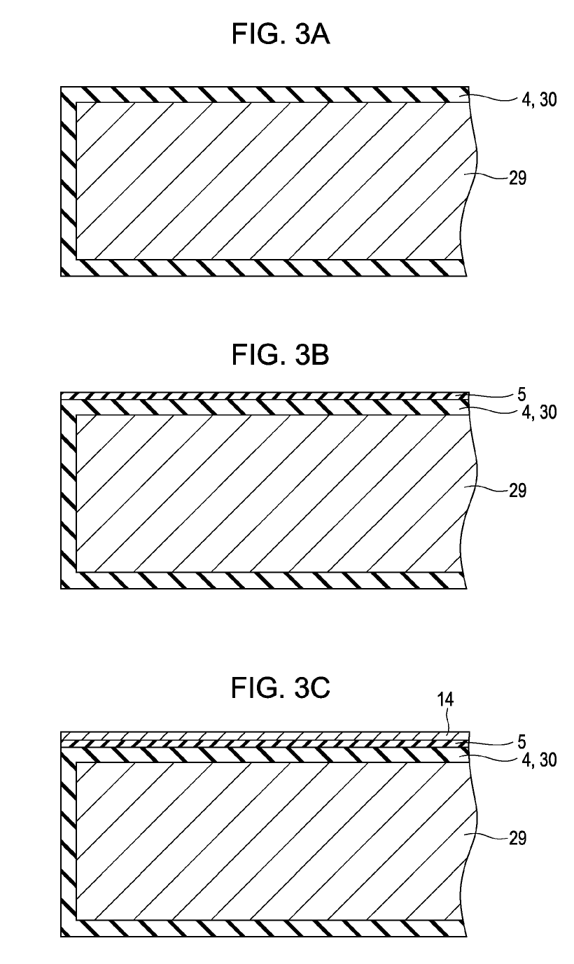

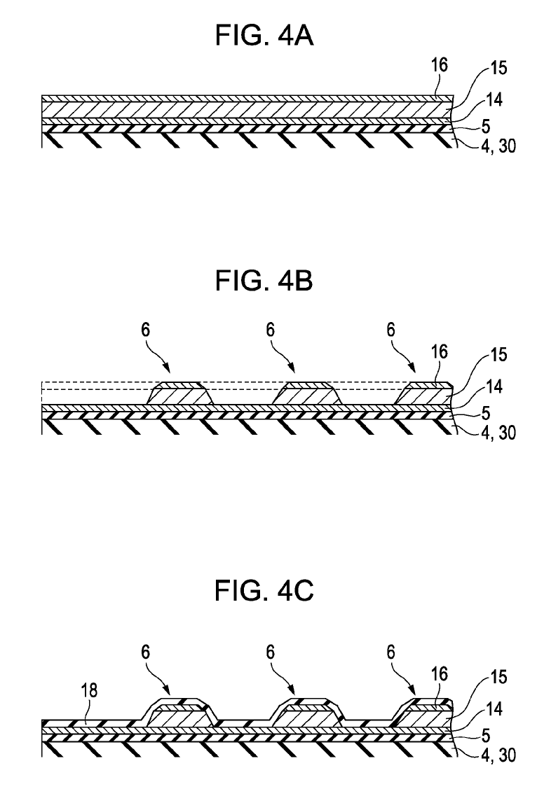

A method of fabricating the above-mentioned recording head 1 will now be described with reference to FIGS. 3A to 4C. FIGS. 3A to 3C are cross-sectional views of the piezoelectric element as taken in the long-length direction of the piezoelectric element which is identical to the longitudinal direction of the pressure-generating chamber 9. FIGS. 4A to 4C are cross-sectional views of the piezoelectric element as taken in the short-length direction of the piezoelectric element to illustrate major parts around the piezoelectric element. First, as shown in FIG. 3A, a wafer 29 for a passage-forming substrate, which is a silicon wafer, is thermally oxidized in a diffusion furnace at a temperature of approximately 1100° C. to form a silicon dioxide film 30, which constitutes the elastic film 4, on the surface of the wafer. Next, as shown in FIG. 3B, the insulation film 5 which is made of zirconium oxide is formed on the elastic film 4. More specifically, for example, a zirconium layer is first formed on the elastic film 4 by, for example, a DC sputtering method or the like. Then, this zirconium layer is thermally oxidized to form the insulation film 5 made of zirconium oxide. And then, as shown in FIG. 3C, the lower electrode film 14 is formed by laminating platinum (Pt) and iridium (Ir) on the insulation film 5.

Thereafter, as shown in FIG. 4A, after the piezoelectric layer 15 made of, for example, lead zirconate titanate (PZT), and the upper electrode film 16 made of, for example, iridium, are formed on the entire surface of the lower electrode film 14, the area opposite to each pressure-generating chamber 9 is patterned to form the piezoelectric element 6, as shown in FIG. 4B. According to the method of forming the piezoelectric layer 15, in this embodiment, the piezoelectric layer 15 made of metal oxide is formed by the so-called sol-gel method, in which a metal-organic compound is dissolved and dispersed in a catalyst to form sol, the sol is turned into gel through application and drying processes, and the gel is baked at a high temperature to obtain the piezoelectric layer 15. The method of forming the piezoelectric layer 15 is not limited to a specific method, and, for example, an MOD (Metal-Organic Decomposition) method or a sputtering method may be employed. When the piezoelectric element 6 is formed, as shown in FIG. 4C, the protective layer 18 is formed on the entire surface of the piezoelectric element 6.

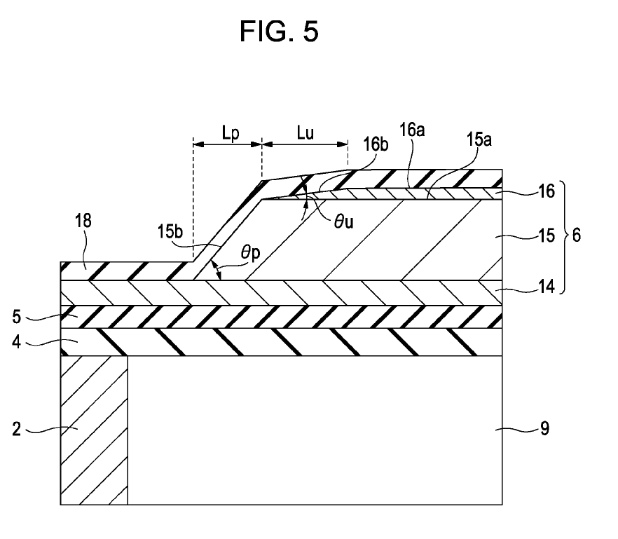

As shown in FIG. 5, the piezoelectric element 6 according to the invention is characterized in that both sides of the piezoelectric layer 15 and the upper electrode film 16 as taken in the short-length direction (width direction) of the element are respectively inclined to the lower electrode film 14 or the passage-forming substrate 2, and in that the piezoelectric layer 15 and the upper electrode film 16 have different inclination angle at the sides thereof. The above feature will now be described in detail. FIG. 5 shows only one of both sides of the piezoelectric layer 15 and the upper electrode film 16 in the short-length direction of the element, but the other side has a shape bilaterally symmetrical to that of the shown side.

The piezoelectric layer 15 includes a flat portion 15a as an upper surface (corresponding to a second surface in the invention) parallel with the lower surface (corresponding to a first surface in the invention) of the lower electrode film 14, and lateral portions 15b of both sides downwardly inclined from the flat portion 15a towards the lower side thereof (the lower electrode film 14 side) in the short-length direction of the element. The lateral portion 15b has an inclination angle of θp (<90°) to the lower surface of the piezoelectric layer 15 (or the lower electrode film 14). Also, the upper electrode film 16 includes a central portion 16a parallel with the flat portion 15a of the piezoelectric layer 15, and a slope portion 16b downwardly inclined from the central portion 16a towards the flat portion 15a. In other words, the slope portion 16b becomes gradually thin from the central portion 16a towards the flat portion 15a. The slope portion 16b has an inclination angle of θu (<90°) to the flat portion 15a of the piezoelectric layer 15, and the inclination angle θu is more gentle than the inclination angle θp of the lateral portion 15b to the lower surface of the piezoelectric layer 15 (that is, θu<θp). For example, θp is in a range of 30° to 60°, while θu is in a range of 2° to 10°. In addition, the lateral portion 15b of the piezoelectric layer 15 has a width Lp of 0.7 μm to 2.3 μm in the short-length direction of the element, while the slope portion 16b of the upper electrode film 16 has a width Lu of 0.3 μm to 1.5 μm in the short-length direction of the element.

The piezoelectric element 6 according to the invention is characterized in that the entire surface of the flat portion 15a of the piezoelectric layer 15 is covered by the upper electrode film 16, as shown in FIG. 5, which will be described in detail hereinafter.

The piezoelectric layer 15 and the upper electrode film 16 are formed in such a way that the width between the inclined upper ends of the lateral portions 15b (i.e., the width of the flat portion 15a) is identical to the width between the inclined lower ends of the slope portions 16b (i.e., the width of the surface adjacent to the piezoelectric layer 15 of the upper electrode film 16). That is, the inclined lower end of the slope portion 16b of the upper electrode film 16 is continuously connected (intersected) to the inclined upper end of the lateral portion 15b of the piezoelectric layer 15. As such, the flat portion 15a of the piezoelectric layer 15 is not exposed, and the whole region (entire width) thereof is covered by the upper electrode film 16.

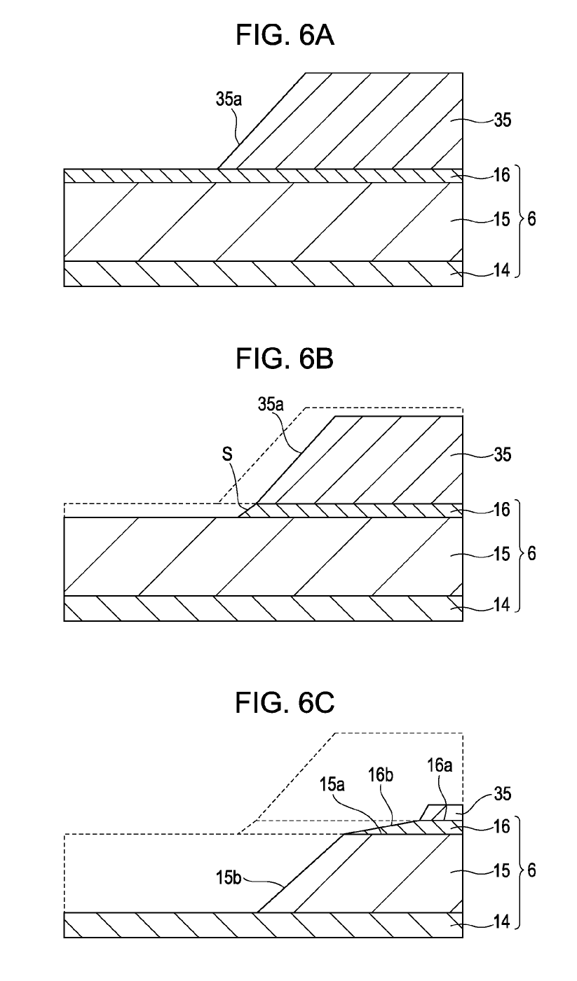

FIG. 6 is a view explaining the process of patterning the above-described piezoelectric element 6. In the patterning process, a photoresist is first applied on the upper surface of the upper electrode film 16, and then is exposed and developed to form a mask layer 35, as shown in FIG. 6A. The mask layer 35 is provided with a tapered surface 35a in order to form the slope portion 16b on the upper electrode film 16 and the lateral portion 15b on the piezoelectric layer 15 by a resist withdrawal method. Then, the upper electrode film is subjected to a first etching process using an etching gas (e.g., an etching gas containing chlorine-based gas) under vacuum, so that the upper electrode film 16 is patterned. In this instance, since the mask layer 35 and the superficial layer of the upper electrode film 16 are etched in sequence, as shown in FIG. 6B, a slope S is formed at an end portion of the upper electrode film 16. Herein, the etch rate of the mask layer 35 is slightly higher than that of the upper electrode film 16, so that the inclination angle of the slope S is smaller than that of the tapered surface 35a of the mask layer 35. Although the patterning is performed by the etching method, the invention is not limited thereto. For example, a reactive ion etching method employing plasma or the like may be used.

After the first etching process is performed to reach the upper surface of the piezoelectric layer 15, the etching conditions (e.g., kinds or concentration of etching gas, or the like) are changed, and then the second etching process is performed. The mask layer 35, the upper electrode film 16, and the piezoelectric layer 15 are etched through the second etching process. The etch rate of the upper electrode film 16 is lower than that of the piezoelectric layer 15. For this reason, the slope formed at the end portion of the piezoelectric layer 15 is much steeper than the slope S formed at the end portion of the upper electrode film 16. Finally, as shown in FIG. 6C, the upper electrode film 16 and the piezoelectric layer 15 are patterned to form the slope portion 16b at both end portions of the upper electrode film 16 and the lateral portion 15b at both end portions of the piezoelectric layer 15, respectively. The slope angles of the slope portion 16b and the lateral portion 15b can be controlled by changing the slope angle of the tapered surface 35a of the mask layer 35, or by changing the etching conditions. If the piezoelectric element 6 is patterned through the above processes, the mask layer 35 is removed, and then the protective layer 18 is formed on the entire surface of the piezoelectric element 6.

With the configuration of the piezoelectric element 6 as described above, the lateral (end) shapes of both sides of the piezoelectric element 6 in a short-length direction from the lower electrode film 14 to the central portion 16a (upper surface) of the upper electrode film 16 through the lateral portion 15b of the piezoelectric layer 15 and the slope portion 16b of the upper electrode film 16 are gentle overall. Therefore, it is possible to reduce stress concentration, in particular, stress concentration applied to both end portions of the upper electrode film 16 in the short-length direction thereof, when the piezoelectric element 6 is driven. Also, since it is possible to prevent the lateral portion 15b of the piezoelectric layer 15 from being inclined above a desired inclination angle level, the stress concentration applied to the boundary between the non-active and active parts of the piezoelectric element 6 can be reduced. As such, breakage of the piezoelectric element 6 due to repeated displacement of the piezoelectric element 6 can be suppressed. As a result, the durability of the piezoelectric element 6 can be improved. In addition, since the thickness of the active part of the piezoelectric element 6 is uniform, it can attempt to equalize the displacement amount or resistance of the piezoelectric element during driving. As such, the driving efficiency can be improved, and rigidity against breakages such as cracks can be obtained.

Since the entire surface of the flat portion 15a of the piezoelectric layer 15 is covered by the upper electrode film 16, it is possible to enlarge an area of the active part of the piezoelectric element 6 to the maximum extent, an electric field is effectively applied to the end portion in a short-length direction of the element, and thus driving efficiency can be improved. Also, since the protective film 18 covers the lower electrode film 14, the piezoelectric layer 15, and the upper electrode film 16, that is, the piezoelectric element 6, the lateral (end) shape of the piezoelectric element 6 is wholly gentle. Sufficient covering thickness of the protective film 18 can be obtained at the corners thereof, and the non-uniform thickness of the protective film 18 can be reduced. In addition, the thickness of the protective film 18 in the active part of the piezoelectric element 6 can be made uniform, and the resistance against the deformation of the piezoelectric element during driving can be made even.

In the recording head 1 including the piezoelectric element 6 which serves as the driving source (pressure generating unit) for ejecting the ink, and the printer including the recording head 1, the piezoelectric element 6 is not easily broken thereby improving the reliability.

The invention is not limited to the above-described embodiment. Although the ink jet-type recording head mounted on an ink jet printer is described as one example, the invention may be applied to an apparatus that ejects a liquid other than ink. For example, the liquid ejecting head may be various recording heads which can be used for an image recording apparatus, for example, a printer, a color material-ejecting head which can be used in an apparatus for fabricating a color filter of a liquid crystal display or the like, an electrode material-ejecting head which can be used in an electrode forming apparatus for an organic EL (Electroluminescence) display or an FED (Field Emission Display), a biological organic substance-ejecting head which can be used to fabricate a biochip, and so forth.

What is claimed is:

1. A piezoelectric element comprising in a laminated state:
a piezoelectric layer;
a first electrode formed on a first surface of the piezoelectric layer; and
a second electrode formed on a second surface of the piezoelectric layer which is opposite to the first surface,
wherein the piezoelectric layer has a film thickness of 5 μm or less, and has a flat portion formed as a second surface in parallel with the first surface, and a lateral portion inclined downwardly from the flat portion towards the first surface,
the second electrode has a central portion formed in parallel with the flat portion, and a slope portion inclined downwardly from the central portion towards the flat portion, and
an inclination angle of the slope portion to the flat portion is gentle as compared with an inclination angle of the lateral portion to the first surface.

2. The piezoelectric element according to claim 1, wherein the second electrode covers the entire surface of the flat portion of the piezoelectric layer.

3. The piezoelectric element according to claim 1, further comprising:
a protective layer that covers the first electrode, the piezoelectric layer and the second electrode.

4. The piezoelectric element according to claim 1, wherein the inclination angle of the slope portion of the second electrode to the flat portion is 2° or more and 20° or less.

5. A liquid ejecting head comprising:
a nozzle orifice;
a pressure-generating chamber communicating with the nozzle orifice; and
a piezoelectric element,
the liquid ejecting head ejecting a liquid from the nozzle orifice due to operation of the piezoelectric element,
wherein the piezoelectric element includes in a laminated state
a piezoelectric layer,
a first electrode formed on a first surface of the piezoelectric layer, and
a second electrode formed on a second surface of the piezoelectric layer which is opposite to the first surface,
the piezoelectric layer has a film thickness of 5 μm or less, and has a flat portion formed as a second surface in parallel with the first surface, and a lateral portion inclined downwardly from the flat portion towards the first surface,
the second electrode has a central portion formed in parallel with the flat portion, and a slope portion inclined downwardly from the central portion towards the flat portion, and
an inclination angle of the slope portion to the flat portion is gentle as compared with an inclination angle of the lateral portion to the first surface.

6. The liquid ejecting head according to claim 5, wherein the second electrode covers the entire surface of the flat portion of the piezoelectric layer.

7. The liquid ejecting head according to claim 5, wherein the inclination angle of the slope portion of the second electrode to the flat portion is 2° or more and 20° or less.

8. A liquid ejecting apparatus comprising:
a liquid ejecting head including a nozzle orifice, a pressure-generating chamber communicating with the nozzle orifice, and a piezoelectric element, the liquid ejecting head ejecting a liquid from the nozzle orifice due to operation of the piezoelectric element,
wherein the piezoelectric element includes in a laminated state
a piezoelectric layer,
a first electrode formed on a first surface of the piezoelectric layer, and
a second electrode formed on a second surface of the piezoelectric layer which is opposite to the first surface,
the piezoelectric layer has a film thickness of 5 μm or less, and has a flat portion formed as a second surface in parallel with the first surface, and a lateral portion inclined downwardly from the flat portion towards the first surface,
the second electrode has a central portion formed in parallel with the flat portion, and a slope portion inclined downwardly from the central portion towards the flat portion, and
an inclination angle of the slope portion to the flat portion is gentle as compared with an inclination angle of the lateral portion to the first surface.

9. The liquid ejecting apparatus according to claim 8, wherein the second electrode covers the entire surface of the flat portion of the piezoelectric layer.

10. The liquid ejecting apparatus according to claim 8, wherein the inclination angle of the slope portion of the second electrode to the flat portion is 2° or more and 20° or less.
